(19) United States
(12) Patent Application Publication
(10) Pub. No.: US 2017/0086299 A1
(43) Pub. Date: Mar. 23, 2017

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventors: Myung-Sam KANG, Hwaseong-si (KR); Sam-Dae PARK, Suwon-si (KR); Tae-Hong MIN, Hwaseong-si (KR); Il-Jong SEO, Cheongju-si (KR); Young-Gwan KO, Seoul (KR)

(73) Assignee: SAMSUNG ELECTRO-MECHANICS CO., LTD., Suwon-si (KR)

(21) Appl. No.: 15/092,043

(22) Filed: Apr. 6, 2016

(30) Foreign Application Priority Data
Sep. 21, 2015 (KR) 10-2015-0133372

(51) Int. Cl. H05K 1/18; H05K 1/02; H05K 1/11; H05K 3/46; H05K 3/06; H01G 4/008; H01G 4/12; H05K 3/40; H05K 1/03; H05K 1/09

(52) U.S. Cl. CPC H05K 1/188; H05K 1/0306; H05K 1/0203; H05K 1/0298; H05K 1/0313; H05K 1/115; H05K 1/09; H05K 3/06; H01G 4/008; H01G 4/1227; H05K 3/4038; H05K 3/46

(57) ABSTRACT

A printed circuit board and a method for manufacturing the same are provided. A printed circuit board according to an example includes a core formed by laminating dielectric substance layers; a capacitor including an internal electrode layer formed between the dielectric substance layers which are adjacent with each other and a connection via alternately connecting the internal electrode layers which are adjacent with each other to provide an electric charge having a different polarity to the internal electrode layers which are adjacent with each other and formed on the core; and a through via passing through the core.

### CROSS REFERENCE TO RELATED APPLICATION(S)

This application claims the benefit under 35 USC 119(a) of Korean Patent Application No. 10-2015-0133372 filed on Sep. 21, 2015 in the Korean Intellectual Property Office, the entire disclosure of which is incorporated herein by reference for all purposes.

### BACKGROUND

1. Field

The following description relates to a printed circuit board. The following description also relates to a method for manufacturing such a printed circuit board.

2. Description of Related Art

As application processors that are mounted in printed circuit boards have become more and more multifunctional, decoupling capacitances, hereinafter referred to as electrostatic capacity, required for the printed circuit boards have gradually increased.

Such a printed circuit board has been prepared by providing a cavity in a printed circuit board and then mounting a capacitor in the cavity. However, such a method that mounts a capacitor in a printed circuit board has a limit in that it is required to provide a thickness of a printed circuit board to be less than that of the capacitor.

In an alternative technology, a substrate with an embedded passive element is disclosed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes a core formed by laminating layers of a dielectric substance, a capacitor comprising internal electrode layers, located between the dielectric substance layers, that are adjacent to each other, and a connection via, alternately connecting the internal electrode layers that are adjacent to each other, to provide an electric charge having a different polarity to the internal electrode layers that are adjacent to each other and located on the core, and a through via that passes through the core.

The printed circuit board may further include a conductive pattern layer located on at least one of the upper surface and the lower surface of the core, an insulating layer comprising an insulating resin located on the conductive pattern layers, and a first via located in the insulating layer.

The printed circuit board may further include a handling layer located between the conductive pattern layers and the core and in which a second via is located.

The dielectric substance may include Al₂O₃.

The dielectric substance may include BaTiO₃.

At least one of the internal electrode layers, the connection via, and the through via may include Ag.

At least one of the internal electrode layers, the connection via, and the through via may include Pd.

Roughness may be provided to increase adhesion between the conductive pattern layer and the insulating layer.

The conductive pattern layer may include Cu.

In another general aspect, a method for manufacturing a printed circuit board includes forming a hole in a sheet of a dielectric substance, forming a conductive paste layer on the sheet of the dielectric substance and forming a middle sheet by filling the hole with a conductive paste, forming a board laminate by multi-layering the middle sheet, and forming a core by sintering the board laminate.

The hole may include a hole for forming a connection via and a hole for forming a through via.

The method may further include, after the step for forming a core, forming a conductive pattern layer on at least one of the upper surface and the lower surface of the core, forming an insulating layer comprising an insulating resin on the conductive pattern layer, and forming a first via in the insulating layer.

The method may further include forming a handling layer on at least one of the upper surface and the lower surface of the core and forming a second via in the handling layer between the forming a core and the forming a conductive pattern layer.

Other features and aspects will be apparent from the following detailed description, the drawings, and the claims.

### BRIEF DESCRIPTION OF THE DRAWINGS

FIG. 1 is a diagram illustrating an example of a printed circuit board.

FIG. 2 is a diagram illustrating another example of a printed circuit board.

FIG. 3 to FIG. 11 are diagrams illustrating an example of a method for manufacturing a printed circuit board.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

It is to be understood that, although the terms “first,” “second,” “third,” “fourth” etc. are used herein to describe various elements, these elements are not to be limited by these terms. These terms are only used to distinguish one element from another. For example, a first element is possibly termed a second element, and, similarly, a second element is possibly termed a first element, without departing from the scope of the present examples. Similarly, when it is described that a method includes series of steps, a sequence of the steps is not a sequence in which the steps should be performed in the sequence, and an arbitrary technical step is optionally omitted and/or another arbitrary step, which is not disclosed herein, is optionally added to the method.

It is to be understood that when terms “left,” “light,” “front,” “rear,” “on,” “under,” “over,” “beneath” or the like are used, the terms are merely used for the purpose of description, and not to describe unchangeable relative positions. The terms used herein are exchangeable to be operated in different directions than shown and described herein under an appropriate environment. It is to be understood that when an element is referred to as being “connected” or “coupled” to another element, it is potentially be directly connected or coupled to the other element or intervening elements are potentially present. In contrast, when an element is referred to as being “directly connected” or “directly coupled” to another element, there are no intervening elements present.

In descriptions of components of the disclosure, a first dielectric substance layer 110a, a second dielectric substance layer 110b, a third dielectric substance layer 110c, a fourth dielectric substance layer 110d, a fifth dielectric substance layer 110e, a sixth dielectric substance layer 110f, a seventh dielectric substance layer 110g and an eighth dielectric substance layer 110h are collectively referred to as a dielectric substance layer if it is not required to distinguish the layers from each other. Also, a first internal electrode layer 210a, a second internal electrode layer 210b, a third internal electrode layer 210c, a fourth internal electrode layer 210d, a fifth internal electrode layer 210e and a sixth internal electrode layer 210f are also collectively referred to as an internal electrode layer if it is not required to distinguish the layers from each other.

A printed circuit board according to an example provides sufficient electrostatic capacity by forming a capacitor on a core that includes a dielectric substance.

Such a printed circuit board, according to an example, ameliorates warpage problems and improves heat releasing performance.

FIG. 1 is a diagram illustrating an example of a printed circuit board.

Referring to the example of FIG. 1, a printed circuit board 1000 according to the example of FIG. 1 includes a core 100, a capacitor 200 and a through via 300. In other examples, the printed circuit board 1000 optionally further includes conductive pattern layers 410, 420, an insulating layer 500 and a first via 600.

For example, the core 100 is formed by laminating dielectric substance layers. In the example of FIG. 1, the core 100 has a multilayered structure of a first dielectric substance layer to an eighth dielectric substance layer 110a to 110h. In this example, the core 100 is formed at the center of the printed circuit board 1000. In such an example, roughness is provided to increase adhesion between the conductive pattern layer 410 and the insulating layer 500 on the upper surface and/or the lower surface of the core 100.

In the example of FIG. 1, the dielectric substance layer is potentially formed of a ceramic material that has a high dielectric constant. For example, the dielectric substance layer optionally includes a ceramic material such as alumina(Al₂O₃) and/or barium titanate(BaTiO₃). However, these are only example ceramic materials and other appropriate ceramic materials are used in other examples.

Since the core 100 is formed with the dielectric substance layer including a ceramic material, the printed circuit board 1000 has greater rigidity and ameliorates warpage problems, compared to issues encountered when the printed circuit board 1000 is formed with a core that includes a resin. Hence, the ceramic material, such as alumina (Al₂O₃), that is used as the core material has a higher thermal conductivity that further improves heat releasing performance of the printed circuit board 1000, as compared to a resin that is alternatively used for the core material.

For example, the capacitor 200 includes an internal electrode layer formed between the dielectric substance layers that are adjacent to each other. The capacitor 200 also includes a connection via that alternately connects the internal electrode layers that are adjacent to each other to provide an electric charge having a different polarity to the internal electrode layers that are adjacent to each other, and is formed on the core 100.

Because the capacitor 200 is formed directly on the core 100 of the printed circuit board 1000, examples are distinguished from alternative techniques that include preparing a board and mounting a capacitor in a cavity of the board.

Also, the internal electrode layer is potentially formed between the dielectric substance layers that are adjacent to each other. For example, as shown in the example of FIG. 1, a first internal electrode layer 210a is formed between a first dielectric substance layer 110a and a second dielectric substance layer 110b that are adjacent to each other. The other internal electrode layers 210b to 201f are optionally formed in a manner similar to that used to form the first internal electrode layer 210a. Also, an electric charge that has a different polarity is optionally provided to the internal electrode layers that are adjacent to each other, such as the first internal electrode layer 210a and the second internal electrode layer 210b. For example, two adjacent internal electrode layers and one dielectric substance layer formed between the two adjacent internal electrode layers function as a capacitor layer. As a particular example, the sequence of layers of first internal electrode layer 210a—the first dielectric substance layer 110b—the second internal electrode layer 210b functions as one capacitor layer.

The connection vias 221, 222 alternately connect the internal electrode layers that are adjacent to each other so as to provide an electric charge that has a different polarity to the internal electrode layers that are adjacent to each other. For example, as shown in the example of FIG. 1, the connection via 221 connects the first, the third and the fifth internal electrode layers 210a, 210c, 210e and the connection via 222 connects the second, the fourth and the sixth internal electrode layers 210b, 210d, 210f. Furthermore, the internal electrode layers that are adjacent to each other are alternately connected to the connection vias 221, 222, such as the first internal electrode layer 210a and the second internal electrode layer 210b.

Thus, one or more capacitors 200 are formed at the portion, except for the portion where the through via 300 is formed, on the core 100 of the printed circuit board 1000. When one capacitor 200 is formed, the through via 300 passes through the capacitor 200 of the core 100. In this example, a pattern is formed on the internal electrode layer so as to be electrically separated from the through via 300.

For example, the through via 300 passes through the core 100. In this example, the through via 300 is formed at the portion where the capacitor 200 is not formed on the core 100. Accordingly, the through via 300 passes through the core 100 so as to connect to a conductive pattern layer 410 formed on the upper surface and the lower surface of the core 100.

Because, in the example of FIG. 1, the internal electrode layer, the connection vias 221, 222 and the through via 300 include a conductive material, electrical signals are transmitted to conductive pattern layers 410, 420 that are formed on the outside of the core 100 through the internal electrode layer, the connection vias 221, 222 and the through via 300.

As least one of the internal electrode layer, the connection vias 221, 222 and the through via 300 possibly includes Ag. Alternatively, at least one of the internal electrode layer, the connection vias 221, 222 and the through via 300 possibly includes Pd. In another example, all of the internal electrode layer, the connection vias 221, 222 and the through via 300 include an alloy of Pd and Ag. However, the conductive material is not to be limited thereto, and other appropriate conductive substances are used in examples in addition to or instead of Pd and Ag.

Also, in the example of FIG. 1, the conductive pattern layers 410, 420 are formed on the upper surface and/or the lower surface of the core 100. For example, the conductive pattern layers 410, 420 include a conductive material to transmit electrical signals. Such a conductive material is optionally Cu but is not to be limited thereto, and other appropriate alternative conductive materials are used in other examples.

It is illustrated in the example of FIG. 1 that the conductive pattern layers 410, 420 are formed on the upper surface and/or the lower surface of the core 100. However, examples are not limited to this approach. For example, the conductive pattern layers 410, 420 are formed on only the upper surface or the lower surface of the core 100, rather than on both surfaces.

In this example, the insulating layer 500 is formed of an insulating resin so as to electrically insulate the conductive pattern layers 410, 420 from each other, by causing them to be formed on different layers.

For example, the insulating layer 500 includes a thermosetting resin such as an epoxy resin, a thermoplastic resin such as polyimide or a photosensitive insulating resin. Here, a thermosensitive material responds to heat, and the photosensitive material responds to light. For example, the insulating layer 500 is formed in a prepreg in which glass fiber is impregnated in an insulating resin, or in a build-up film in which a filler is included in an insulating resin. However, these are only examples and other appropriate resins are used in other examples.

For example, the first via 600 is formed so as to pass through the insulating layer 500 and to electrically connect the conductive pattern layers 410, 420 with one another because they are formed via the insulating layer 500 in different layers. For example, the first via 600 is formed by forming a via hole in the insulating layer 500 and then filling the via hole using a conductive material or plating the via hole using a conductive material.

For example, the first via 600 is optionally formed of any conductive material that is used as a conductive metal. In an example, when the conductive pattern layers 410, 420 are formed of Cu, the first via 600 is also formed of Cu. In this example, adhesion between the first via 600 and conductive pattern layers 410, 420 is improved due to the choice of material.

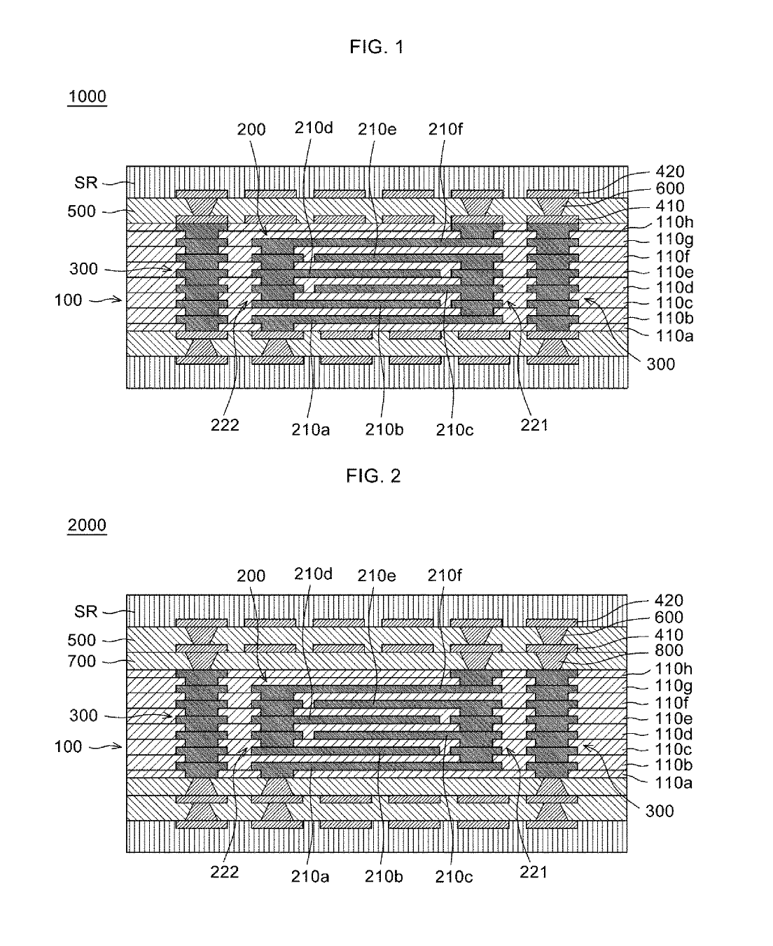

FIG. 2 is a diagram illustrating another example of a printed circuit board.

Referring to the example of FIG. 2, a printed circuit board 2000 according to another example further includes a handling layer 700 and a second via 800 in addition to the elements of the printed circuit board 1000.

For example, the handling layer 700 is formed between the conductive pattern layer 410 and the core 100, and the second via 800 is formed in the handling layer 700. Also, the conductive pattern layer 410 is formed on the upper surface and the lower surface of the core 100 in the printed circuit board 1000. However, the handling layer 700 is alternatively formed on the upper surface and the lower surface of the core 100 and accordingly the conductive pattern layer 410 is then formed on the handling layer 700 in the printed circuit board 2000.

For example, the handling layer 700 facilitates handling of the core 100 and prevents the core 100 from being exposed to the outside during the processing, avoiding possible contamination. In this example, the handling layer 700 includes a thermosetting resin such as an epoxy resin, a thermoplastic resin such as polyimide or a photosensitive insulating resin. For example, the handling layer 700 is formed in a prepreg in which glass fiber is impregnated in an insulating resin or in a build-up film in which a filler is included in an insulating resin. However, these are only examples and other appropriate resins are used in other examples.

Furthermore, the second via 800 connects between the through via 300 and the conductive pattern layer 410 and between the capacitor 200 and the conductive pattern layer 410. Also, the second via 800 is formed by forming a via hole in the handling layer 700 and then filling the via hole using a conductive material or plating the via hole using a conductive material.

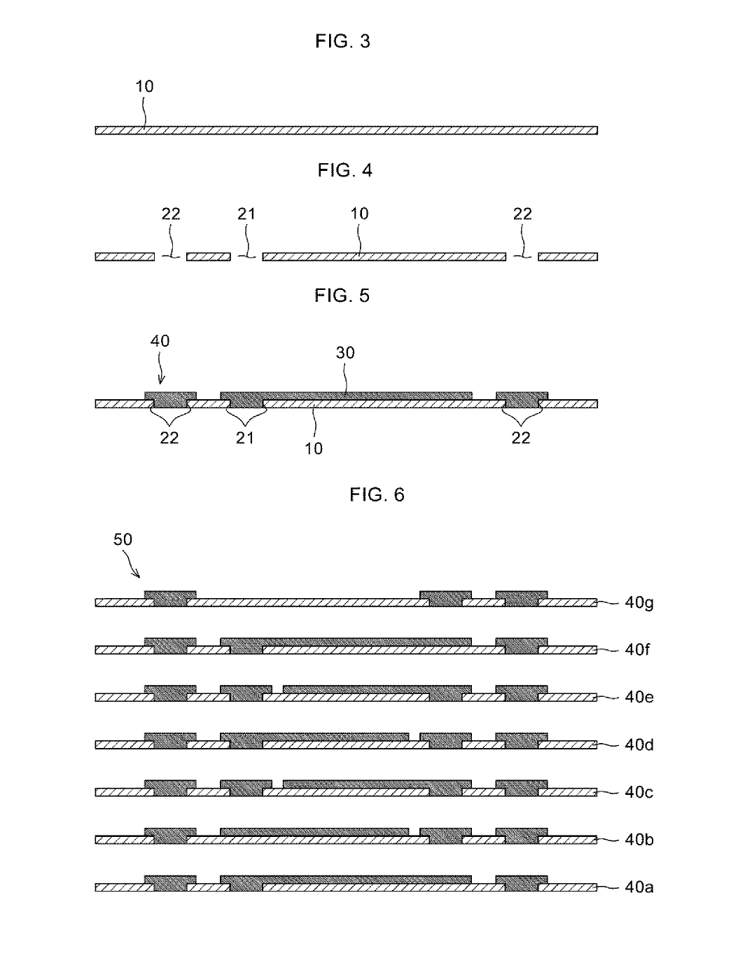

FIG. 3 to FIG. 11 are diagrams illustrating an example of a method for manufacturing a printed circuit board.

Referring to the examples of FIG. 3 and FIG. 4, a method for manufacturing a printed circuit board 1000 includes forming a hole in a dielectric substance sheet 10.

In an example, the dielectric substance sheet 10 is formed of ceramic powder having a high dielectric constant. For example, the dielectric substance sheet 10 is formed of a ceramic powder such as alumina (Al₂O₃) and barium titanate (BaTiO₃). However, in other examples, other appropriate materials are used to form the dielectric substance sheet 10. The dielectric substance sheet 10 is formed as a sheet by mixing additives such as ceramic powder and a binder to provide slurry and performing a doctor blade method.

For example, holes 21, 22 are formed in the dielectric substance sheet 10. More specifically, in this example, the holes 21, 22 in the dielectric substance sheet 10 include a hole for forming a connection via 21 and a hole for forming a through via 22. In an example, the holes 21, 22 are formed through a CNC drilling technique, which refers to Computerized Numerical Control drilling in which a computer controls operation of the drill that forms the holes 21, 22. However, the method for forming the holes 21, 22 is not limited to CNC drilling and other appropriate techniques are used in other examples.

Referring to the example of FIG. 5, the method for manufacturing a printed circuit board 1000 includes forming a conductive paste layer 30 on the dielectric substance sheet 10 and forming a middle sheet 40 by filling the holes 21, 22 with a conductive paste.

For example, the conductive paste is filled into the holes 21, 22 of the dielectric substance sheet 10 and is coated on the dielectric substance sheet 10 to form the conductive paste layer 30.

In this example, the conductive paste includes a conductive metal having a melting temperature higher than a sintering temperature of the dielectric substance sheet. Here, sintering is the process of compacting and forming a solid mass of material by heat and/or pressure without melting it to the point of liquefaction. For example, the conductive metal is an alloy of Pd and Ag. However, in other examples, the conductive metal includes other appropriate materials.

For example, the middle sheet 40 is formed by coating the conductive paste layer 30 onto the dielectric substance sheet 10.

Referring to the example of FIG. 6, the method for manufacturing a printed circuit board 1000 includes forming a board laminate 50 by laminating middle sheets 40a to 40g.

For example, the board laminate 50 is formed by sequentially laminating middle sheets 40a to 40g based on a reference hole, not shown.

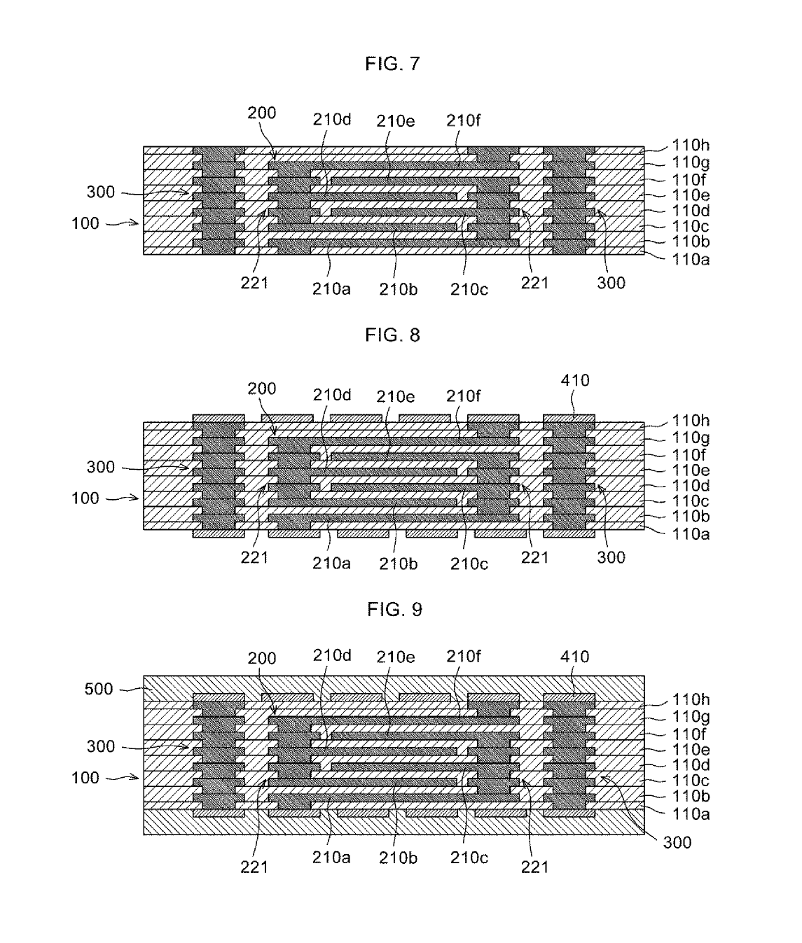

Referring to the example of FIG. 7, the method for manufacturing a printed circuit board 1000 includes forming a core 100 by sintering the board laminate 50.

Thus, in the example of FIG. 7, the core 100 is formed by sintering the board laminate 50. For example, the sintering of the board laminate 50 is performed at a sintering temperature of the ceramic powder included in the dielectric substance sheet 10. Here, the dielectric substance sheet 10 is sintered to the dielectric substance layers 110a to 110h and the conductive paste layer 30 is sintered to the internal electrode layers 210a to 210f. The conductive paste filling the hole for forming the connection via 21 and the conductive paste filling the hole for forming the through via 22, formed on the dielectric substance sheet 10, are further sintered to the connection vias 221, 222 and the through via 300, respectively.

Referring to the example of FIG. 8, the method for manufacturing a printed circuit board 1000 includes forming a conductive pattern layer 410 on the upper surface and/or the lower surface of the core 100 after forming the core 100.

For example, the conductive pattern layer 410 is formed by forming a conductive film on the upper surface and/or the lower surface of the core 100. The conductive pattern layer 410 is also formed by selectively eliminating the conductive film through an etching process, such as a subtractive process, or an additive process, such as a full additive process, a semi-additive process, or a modified semi-additive process, that selectively forms conductive patterns. However, detailed description of the subtractive process or the additive process is omitted for brevity.

Referring to the example of FIG. 9, the method for manufacturing a printed circuit board 1000 includes forming an insulating layer 500 including an insulating resin on the conductive pattern layer 410.

In the example of FIG. 9, the insulating layer 500 includes a thermosetting resin such as an epoxy resin, a thermoplastic resin such as polyimide or a photosensitive insulating resin. Also, the insulating layer 500 is possibly formed in a prepreg in which glass fiber is impregnated in an insulating resin or in a build-up film in which a filler is included in an insulating resin. However, these are only examples and other appropriate resins are used in other examples.

For example, the insulating layer 500 is formed by arranging an insulating film including an insulating resin on the core 100 on which the conductive pattern layer 410 is formed and heating and compressing the resulting structure. In another example, the insulating layer 500 is also formed by coating a liquid insulating material on one surface of the core 100 on which the conductive pattern layer 410 is formed and then hardening the resulting structure.

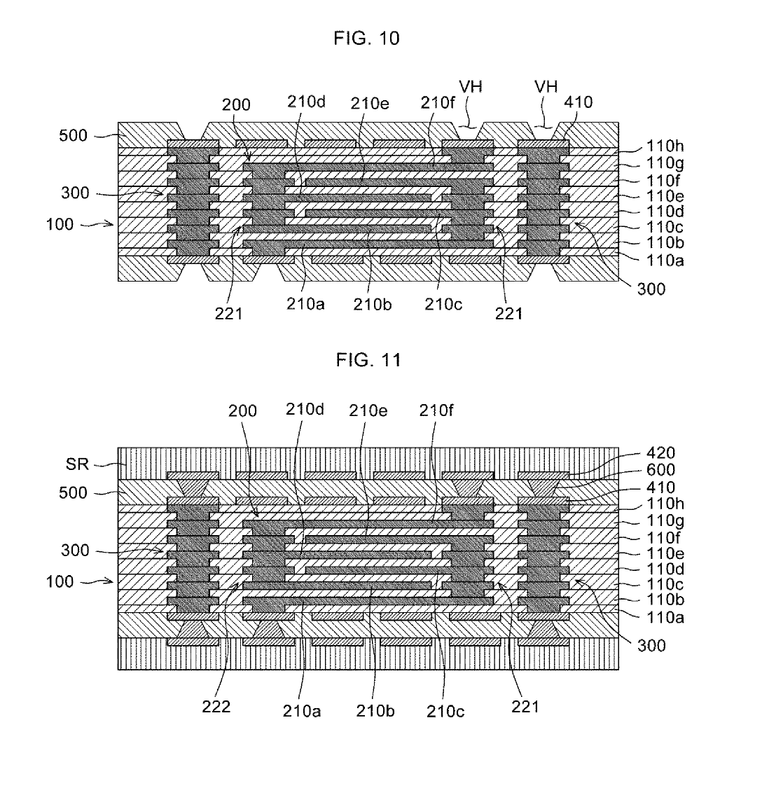

Referring to the examples of FIG. 10 and FIG. 11, the method for manufacturing a printed circuit board 1000 includes forming a first via 600 in the insulating layer 500 and forming another conductive pattern layer 420 on the insulating layer 500.

In the examples of FIG. 10 and FIG. 11, the first via 600 is formed by forming a via hole VH in the insulating layer 500 and then filling the via hole VH with a conductive material. The conductive pattern layer 420 formed on the insulating layer 500 is formed through the subtractive process or the additive process, as discussed further previously. When the conductive pattern layer 420 is formed through the additive process, the first via 600 and the conductive pattern layer 420 are potentially formed at the same time.

When the conductive pattern layer 420 is the outmost layer, after the conductive pattern layer 420 is formed, a solder resist layer SR is also potentially formed on the conductive pattern layer 420.

A method for manufacturing a printed circuit board 2000 is possibly the same method used for manufacturing the printed circuit board 1000. However, the method for manufacturing the printed circuit board 2000 potentially further includes forming a handling layer 700 on the upper surface and/or the lower surface of the core 100 between the step for forming the core 100 and the step for forming the conductive pattern layer 410. The method for manufacturing the printed circuit board 2000 potentially further includes forming a second via 800 on the handling layer 700. The method for manufacturing the printed circuit board 2000 is explained further with reference to the example of FIG. 2.

Referring to the example of FIG. 2, the handling layer 700 is formed on the upper surface and/or the lower surface of the core 100 to facilitate handling of the core 100 and to prevent the core 100 from being exposed to the outside during the processing. Preventing the core 100 from being exposed to the outside during the processing is helpful in that it helps avoid contamination.

For example, the handling layer 700 include a thermosetting resin such as an epoxy resin, a thermoplastic resin such as polyimide or a photosensitive insulating resin. The handling layer 700 may be formed in a prepreg in which glass fiber is impregnated in an insulating resin or in a build-up film in which a filler is included in an insulating resin. However, these are only examples and other appropriate resins are used in other examples.

For example, the second via 800 connects between the through via 300 and the conductive pattern layer 410 and between the capacitor 200 and the conductive pattern layer 410. In such an example, the second via 800 is formed by forming a via hole in the handling layer 700 and then filling the via hole with a conductive material or plating the via hole with a conductive material.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation,

Expressions such as “first conductivity type” and “second conductivity type” as used herein may refer to opposite conductivity types such as N and P conductivity types, and examples described herein using such expressions encompass complementary examples as well. For example, an example in which a first conductivity type is N and a second conductivity type is P encompasses an example in which the first conductivity type is P and the second conductivity type is N.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board, comprising:
a core formed by laminating layers of a dielectric substance;
a capacitor comprising internal electrode layers, located between the dielectric substance layers, that are adjacent to each other, and a connection via, alternately connecting the internal electrode layers that are adjacent to each other, to provide an electric charge having a different polarity to the internal electrode layers that are adjacent to each other and located on the core; and
a through via that passes through the core.

2. The printed circuit board of claim 1, further comprising:
a conductive pattern layer located on at least one of the upper surface and the lower surface of the core;
an insulating layer comprising an insulating resin located on the conductive pattern layers; and
a first via located in the insulating layer.

3. The printed circuit board of claim 2, further comprising a handling layer located between the conductive pattern layers and the core and in which a second via is located.

4. The printed circuit board of claim 1, wherein the dielectric substance comprises Al₂O₃.

5. The printed circuit board of claim 1, wherein the dielectric substance comprises BaTiO₃.

6. The printed circuit board of claim 1, wherein at least one of the internal electrode layers, the connection via, and the through via comprises Ag.

7. The printed circuit board of claim 1, wherein at least one of the internal electrode layers, the connection via, and the through via comprises Pd.

8. The printed circuit board of claim 1, wherein roughness is provided to increase adhesion between the conductive pattern layer and the insulating layer.

9. The printed circuit board of claim 1, wherein the conductive pattern layer comprises Cu.

10. A method for manufacturing a printed circuit board, comprising:
forming a hole in a sheet of a dielectric substance;
forming a conductive paste layer on the sheet of the dielectric substance and forming a middle sheet by filling the hole with a conductive paste;
forming a board laminate by multi-layering the middle sheet; and
forming a core by sintering the board laminate.

11. The method of claim 10, wherein the hole comprises a hole for forming a connection via and a hole for forming a through via.

12. The method of claim 10, further comprising, after the step for forming a core:
forming a conductive pattern layer on at least one of the upper surface and the lower surface of the core;
forming an insulating layer comprising an insulating resin on the conductive pattern layer; and
forming a first via in the insulating layer.

13. The method of claim 12, further comprising forming a handling layer on at least one of the upper surface and the lower surface of the core and forming a second via in the handling layer between the forming a core and the forming a conductive pattern layer.
